(19) United States
(12) Patent Application Publication
(10) Pub. No.: US 2025/0220863 A1
(43) Pub. Date: Jul. 3, 2025

(54) STATIONARY INDUCTION CHARGING DEVICE

(71) Applicant: MAHLE International GmbH, Stuttgart (DE)

(72) Inventors: Stefan Dold, Godella (ES); Jaime Espinosa, Nules (ES); Thomas Himmer, Reichenbach (DE); Roberto Montes, Valencia (ES); Holger Schroth, Maulbronn (DE)

(21) Appl. No.: 18/850,050

(22) PCT Filed: Feb. 9, 2023
(86) PCT No.: PCT/EP2023/053154

§ 371 Date: Sep. 23, 2024

(30) Foreign Application Priority Data
Mar. 24, 2022 (DE) 10 2022 202 925.9

(51) Int. Cl. H05K 7/20; B60L 53/122; B60L 53/302; H02J 50/00; H02J 50/10; H02J 50/70

(52) U.S. Cl. CPC H05K 7/20909; B60L 53/122; B60L 53/302; H02J 50/005; H02J 50/10; H02J 50/70; H05K 7/20145; H05K 7/20336

(57) ABSTRACT

A stationary induction charging device for an inductive vehicle charging system for charging the battery for a battery-electric vehicle is disclosed. The charging device includes a device housing, at least one coil in the device housing, a power electronics in the device housing, and an air cooling device. The air cooling device has at least one air shaft running into the device housing for guiding air, at least one fan for driving the air, at least one air inlet fluidically connecting the at least one air shaft to the surroundings, and at least one air outlet fluidically connecting the at least one air shaft to the surroundings. The air shaft comprises at least one heat transfer area, in which a shaft wall is coupled to an exterior wall facing away from the interior wall with at least one component of the power electronics.

### CROSS-REFERENCE TO RELATED APPLICATIONS

This application claims priority to International Patent Application No. PCT/EP2023/053154 filed Feb. 9, 2023, which also claims priority to German Patent Application DE 10 2022 202 925.9 filed Mar. 24, 2022, the contents of each of which is hereby incorporated by reference in its entirety.

### TECHNICAL FIELD

The present invention relates to a stationary induction charging device, which is preferably used in an inductive vehicle charging system that is used to charge the battery for a battery-electric vehicle. The invention also relates to an inductive vehicle charging system equipped with such a stationary induction charging device.

### BACKGROUND

Such a vehicle charging system comprises a stationary induction charging device, which can also be referred to as a ground assembly and which is usually arranged in a fixed location, for example at a vehicle parking space, and connected to an electrical power grid, and a mobile induction charging device, which can also be referred to as a vehicle assembly and which is set up on the vehicle involved. The mobile induction charging device is in this case appropriately coupled to the battery of the vehicle, e.g. via a corresponding vehicle-side charger. To charge the battery, the vehicle is positioned with its mobile induction charging device with respect to the stationary induction charging device in such a way that electrical energy can be transferred from the stationary induction charging device to the mobile induction charging device by means of induction, i.e. via an electromagnetic alternating field. With the inductive vehicle charging system, charging plugs that have to be plugged in with vehicle-side charging sockets are not required.

A stationary induction charging device comprises a device housing, which comprises a housing base and a housing cover spaced apart from the housing base in a height direction of the induction charging device. Furthermore, such a stationary induction charging device comprises at least one coil located in the device housing for generating an electromagnetic alternating field, which can also be referred to as a resonator coil, as well as a power electronics located in the device housing for supplying energy to the coil and for controlling the coil. During operation of the stationary induction charging device, heat is generated in components of the power electronics. At high power, a comparative amount of heat is generated that must be dissipated to avoid damage to the power electronics or to increase the lifespan of the power electronics.

Air cooling devices are generally known for dissipating heat from a power electronics system or for cooling a power electronics system, which generate an air flow by means of a blower in such a way that it flows around the relevant components of the power electronics. Accordingly, an air cooling device uses an air flow for cooling. Such air cooling devices are used in computers, for example.

A stationary induction charging device must be designed to be drivable, so that it must be comparatively small in height and sufficiently stable. It is also necessary to shield the power electronics against the alternating electromagnetic field generated by the coil, whereby this shielding can enclose the power electronics on all sides. This eliminates the use of a conventional air cooling device, in which the relevant components of the power electronics are directly circulated with air from the surroundings of the induction charging device in order to dissipate heat.

The present invention addresses the problem of providing an embodiment for a stationary induction charging device and a vehicle charging system equipped with it, which is characterized by efficient cooling of the power electronics.

According to the invention, this problem is solved by the subject-matter of the independent claim(s). Advantageous embodiments are the subject of the dependent claims.

### SUMMARY

The invention is based on the general idea of equipping the air cooling device with at least one air shaft running in the device housing for guiding air, which has a shaft wall made of metal, which is exposed to the air flow on its inner wall side and is coupled to at least one component of the power electronics in a heat-transfer manner on its exterior wall surface. During operation of the induction charging device presented here, the heat from the relevant components of the power electronics is transferred via the outside of the wall to the shaft wall and dissipated by the air flow on the inside of the wall. Since the shaft wall is made of metal, it forms a good heat conductor. In particular, the components in the shaft wall, which are locally and quasi point-like coupled in a heat transmitting manner to the outside of the wall, are distributed over a large area on the inside of the wall, which improves the heat transfer to the air. The efficient heat dissipation supports the compact invention of the induction charging device. At the same time, the electromagnetic shielding of the power electronics can be maintained.

In detail, the invention proposes the air cooling device has at least one air shaft extending in the device housing for guiding air, at least one blower arranged in the equipment housing for driving the air in the air shaft, at least one air inlet fluidically connecting the air shaft to the surroundings of the induction charging device and at least one air inlet formed on the device housing, the air shaft has an air outlet that connects fluidically to the surroundings. Furthermore, the respective air shaft has a shaft wall made of metal, which is exposed to the air on an interior wall. Furthermore, the air shaft has at least one heat exchanger region in which the shaft wall is coupled to at least one component of the power electronics in a heat-transfer manner on an exterior wall surface facing away from the interior wall surface. In the respective air shaft, heat transfer areas are therefore defined on the shaft wall, in which the outside of the wall is coupled to at least one component of the power electronics to be cooled in a heat-transmitting manner. It is clear that the air cooling device can have a plurality of air shafts, each having such a shaft wall with at least one heat exchanger region. It is also clear that the shaft wall can have several such heat transfer areas in the respective air shaft.

In an advantageous embodiment, at least in such a heat exchanger region, a heat exchanger structure can be arranged in the air shaft on the inside of the wall, through which air can flow and which is coupled to the inside of the wall in a heat-transferring manner. The heat transfer structure is used to transfer the heat from the inside of the wall to the air. Such a heat transfer structure can in particular be characterized by a large surface that is exposed to the air flow. Such heat exchanger structures can, for example, have or be formed by fins, lamellae, turbulators. The heat transfer structure is preferably made of metal. The heat-transmitting coupling to the interior of the wall can occur through a flat contact, preferably in connection with a soldering connection or welded connection or adhesive connection or screw connection.

In an advantageous development, at least one such heat exchanger structure can have fins around which the air can flow. These ribs can expediently run parallel to each other, whereby the ribs run parallel to the main flow direction defined by the air shaft.

According to one advantageous embodiment, at least one such heat transfer structure can comprise at least one heat pipe that dissipates heat from the interior of the wall. Such a heat pipe is generally a heat exchanger that allows a high heat flux density by utilizing the evaporation enthalpy of a medium. The heat pipe can be designed as a heat pipe or as a two-phase thermosiphon. The respective heat pipe can specifically be coupled in a heat transmitting manner to the above-mentioned ribs.

According to another embodiment, at least one such heat transfer structure can comprise at least one rib, which projects from the shaft wall on the inside of the wall, which extends parallel to a shaft side wall adjacent to the air shaft and which is supported by a plurality of flat tube blocks on the respective shaft side wall. While the shaft wall limits the air shaft downwards or upwards, i.e. in the height direction, the respective shaft side wall limits the air shaft transversely to the height direction. The respective rib is coupled in a heat transmitting manner to the respective shaft side wall via the flat tube blocks. In detail, the plurality of flat tube blocks are arranged one behind the other and spaced apart from one another in the flow direction of the air. This creates a cascading arrangement of the heat transfer. The respective flat tube block comprises a plurality of flat pipes that the air can flow through, which are arranged adjacent to one another transversely to the direction of flow of the air and are connected to one another in a heat-transferring manner. The flat pipes are characterized by their height being significantly smaller than their width and their length. By providing several flat pipes in the respective flat pipe block, the surface area provided for the transfer of heat to the air is significantly increased. For this reason, flat tube blocks of the type described above can preferably be arranged in regions in which components of the power electronics, which are characterized by a particularly high heat output, are coupled to the outside of the wall of the shaft wall in a heat-transmitting manner. Furthermore, the respective rib can be a large solid body or, alternatively, a tubular hollow body that can flow through air, in particular a further flat tube.

In a standing arrangement, the respective flat tube block can in particular have an outer flat tube facing the respective shaft side wall, which is coupled to the respective shaft side wall in a heat-transferring manner, and an inner flat tube facing away from the respective shaft side wall, which is coupled to the respective fin in a heat-transferring manner. In the case of three or more flat pipes within the flat pipe block, at least one central flat pipe is arranged between the outer flat pipe and the inner flat pipe and is coupled in a heat transmitting manner to the adjacent flat pipes.

In a horizontal arrangement, the respective flat tube block can in particular have an upper flat tube facing away from the shaft wall, which is coupled to the respective shaft side wall and the respective rib and/or to a boundary wall opposite the shaft wall in a heat-transferring manner, and a lower flat tube facing the shaft wall, which is coupled to the respective rib and to the respective shaft side wall and/or to the shaft wall in a heat-transferring manner. In the case of three or more flat pipes within the flat pipe block, at least one central flat pipe is arranged between the upper flat pipe and the lower flat pipe and is coupled in a heat transmitting manner to the adjacent flat pipes.

In an advantageous embodiment, the air shaft can have two such side walls in at least one such heat exchanger region, which run parallel to one another. The heat exchanger structure arranged in this heat exchanger region can then comprise two such ribs, which then form two outer ribs. One outer rib is then supported on one side wall of the shaft via several such flat tube blocks, while the other outer rib on the other side wall of the shaft is supported via several such flat tube blocks. This results in a symmetrical structure that enables efficient heat transfer from the shaft wall to the air via the ribs and the shaft side walls in connection with the flat tube blocks.

In another embodiment, the heat transfer structure can also comprise at least one inner rib that projects from the shaft wall on the inside of the wall, which extends parallel to the outer ribs and is arranged between the outer ribs. The respective inner rib likewise dissipates heat from the shaft wall and can be supported on the one hand by a plurality of such flat tube blocks on one of the outer ribs. On the other hand, the respective inner rib can be supported by several such flat tube blocks on the other outer rib or on another inner rib. In particular, it can be provided that three or more inner ribs are provided, so that at least one inner rib is supported on the one hand by a plurality of flat tube blocks on adjacent inner ribs. The ribs channel the air shaft within the heat transfer structure. The ribs and the shaft side walls dissipate the heat from the shaft wall. The flat pipe blocks remove the heat from the shaft side walls and the ribs and transfer them to the air flow. Here, too, the outer ribs and/or the respective inner rib can be designed as a solid body or as tubular hollow bodies that air can flow through, in particular as further flat tubes.

In another embodiment, a plurality of pressure supports that can be circulated by the air can be arranged in the air shaft and/or in at least one such heat transfer structure, which transfer pressure forces extending in the height direction between the shaft wall and a limiting wall of the air shaft opposite the shaft wall. The pressure supports can be rod-shaped or column-shaped and can be made of metal. In particular, the pressure supports can penetrate the shaft wall and/or the opposite partition wall. The pressure supports are used to stabilize the air shaft so that the equipment housing can be driven over.

In order to improve the heat transfer from the component of the power electronics to be cooled to the shaft wall, additional measures can be provided that can be used alternatively or cumulatively. For example, at least one component of the power electronics can be preloaded against the outside of the wall by means of a spring device. The pretensioning improves the surface contact and thereby improves the heat transfer. At least one component of the power electronics can be coupled in a heat transmitting manner to the outside of the wall by means of a heat pipe. This makes it possible, for example, to efficiently couple a component, which has a comparatively large distance from the outside of the wall, to said component in a heat-transmitting manner. At least one component of the power electronics can be coupled in a heat transmitting manner to the outside of the wall by means of a heat conductor, such as a thermal conductive film, a thermal conductive pad, a thermal paste, or a thermal conductive gel.

In another embodiment, the shaft wall can be formed by a section of a shielding plate that covers the power electronics towards the bottom of the housing or toward the housing cover. For example, the shielding plate can cover the power electronics towards the bottom of the housing and in particular, together with the bottom of the housing, can delimit a space in which the power electronics are located. For this purpose, the housing base should be made of a metal. Alternatively, the shaft wall can be formed by a section of a shielding housing, which is arranged in the device housing and in which the power electronics are arranged. The shield housing is preferably made of a metal. By forming the shaft wall through a section of a shielding plate or a shielding housing, a component present in the induction charging device within the air cooling device is therefore used anyway. This supports a compact design and simultaneously leads to efficient heat transfer. It is noteworthy that the respective section is formed only by a part of the shielding plate or the shielding housing. Therefore, only a partial area of the shielding plate or the shielding housing is used to form the shaft wall in order to effect the air guidance in the air shaft. This makes it possible to better utilize the existing installation space within the device housing.

In one embodiment, it can be provided that the shaft wall is adapted in the height direction to a topology of the power electronics. The air shaft therefore has a shaft height measured in the height direction, which varies in the flow direction of the air according to the topology of the power electronics. Higher and lower components can alternate within the power electronics with regard to the height direction. Adapting the shaft wall to the topology of the power electronics reduces the distances between the components and the shaft wall and simplifies the heat-transmitting coupling between the components to be cooled and the shaft wall.

In another embodiment, the air shaft can have a shaft width transverse to the flow direction of the air that varies in the flow direction of the air and/or have a cross-section through which air can flow, which varies in the flow direction of the air. The cross-section of the air shaft or the shaft width that can flow through can form a constriction in the respective heat exchanger area. In other words, the shaft width or the cross-section through which the fluid can flow increases in the flow direction towards the respective heat exchanger region and then increases again. By reducing the shaft width or the cross-section the air flow rate is increased, which promotes heat dissipation in the heat transfer area.

In another embodiment, the device housing can have a frame structure that laterally surrounds the device housing. The frame structure can be ramp-shaped or wedge-shaped in a cross-section running parallel to the height direction in order to promote the ability to drive over the induction charging device. The frame structure can expediently comprise at least one air-permeable inlet region to which the respective air inlet is connected. In addition, the frame structure can comprise at least one air-permeable outlet region away from the inlet region, to which the respective air outlet is connected. The permeability for air can be determined in the respective frame region by a plurality of inlet openings or outlet openings. By housing the air inlet and air outlet in the frame structure, a comparatively long flow path for the air within the respective air shaft can be achieved, which promotes efficient heat transfer.

The frame structure can also be used to accommodate further important components of the air cooling device. For example, at least one blower can be arranged at the respective air inlet in the respective inlet region. Additionally or alternatively, at least one blower can be arranged at the respective air outlet in the respective outlet region. Additionally or alternatively, at least one blower can be arranged at any position within the air shaft, for example in order to give the air flow better continuity and/or to reduce the noise emission into the surroundings, e.g. by means of a cascaded arrangement or series connection of several blowers. Additionally or alternatively, an air filter can be arranged in the respective inlet region.

According to another advantageous embodiment, the air shaft can comprise at least three shaft sections, which are connected to one another via a branch, wherein the branch office divides an incoming air flow into two or more outgoing air flows or aggregates two or more incoming air flows into an outflowing air flow. Furthermore, it can in particular be provided that at least one heat transfer area is formed in each of these shaft sections.

An inductive vehicle charging system according to the invention, which is used to charge a battery of a battery-electric vehicle, is equipped with a stationary induction charging device of the type described above and with a mobile induction charging device that is arranged on the respective vehicle. In the operational state, the stationary induction charging device is stationary in or on the background of a vehicle parking space and is electrically connected to a power grid. The mobile induction charging device is arranged on the bottom of the vehicle and is electrically connected to a battery charger arranged in the vehicle, which in turn is electrically connected to the battery of the vehicle.

Further important features and advantages of the invention are apparent from the subclaims, from the drawings and from the associated description of the figures with reference to the drawings.

It is understood that the above-mentioned features and those yet to be explained below can be used not only in the combination indicated in each case, but also in other combinations or on their own, without deviating from the scope of the invention. The above-mentioned components of a superordinate unit, such as a device, an apparatus, or an arrangement, which are designated separately, can form separate parts or components of this unit or be integral areas or sections of this unit, even if this is shown differently in the drawings.

Preferred exemplary embodiments of the invention are shown in the drawings by way of example and will be explained in more detail in the following description, wherein identical reference numbers refer to identical or similar or functionally identical elements.

### BRIEF DESCRIPTION OF THE DRAWINGS

It shows, in each case schematically,

FIG. 1 a significantly simplified, principal cross-section of a stationary induction charging device corresponding to section lines I in FIG. 2.

FIG. 2 a significantly simplified transparent top view of the induction charging device of FIG. 1,

FIG. 3 a cross-section of the induction charging device, as in FIG. 1, but in another embodiment,

FIG. 4 a transparent top view of the induction charging device as in FIG. 2, but in the embodiment according to FIG. 3,

FIG. 5 an enlarged sectional view of the induction charging device in the region of an air shaft,

FIG. 6 a sectional view as in FIG. 5, but in a different embodiment,

FIG. 7 a significantly simplified isometric view in the region of a free-cut heat exchanger structure.

### DETAILED DESCRIPTION

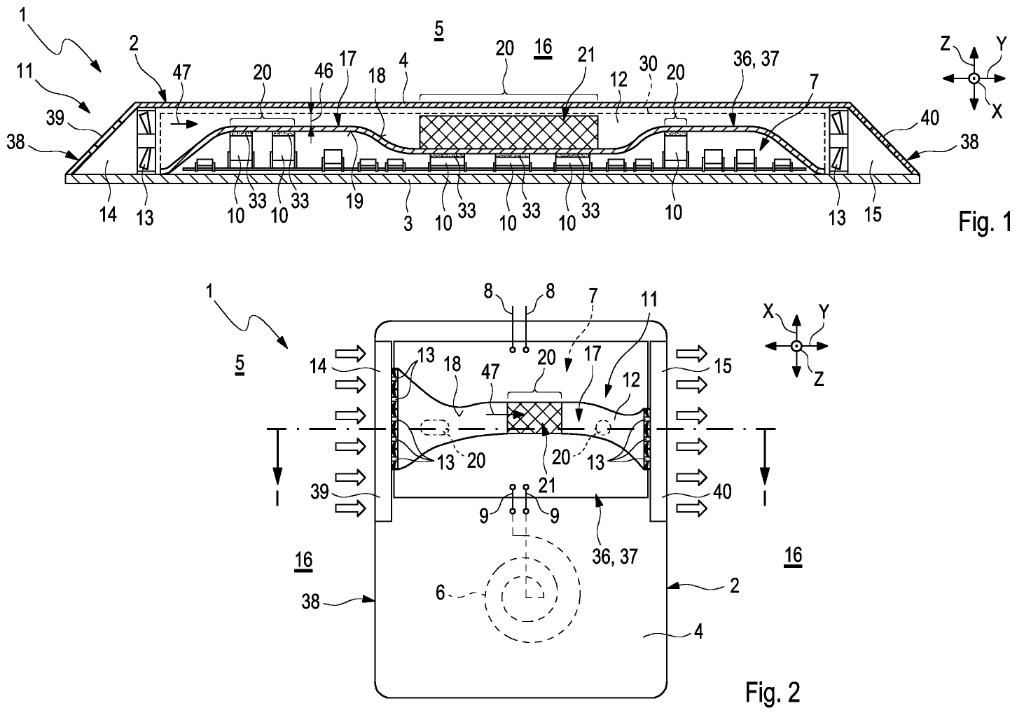

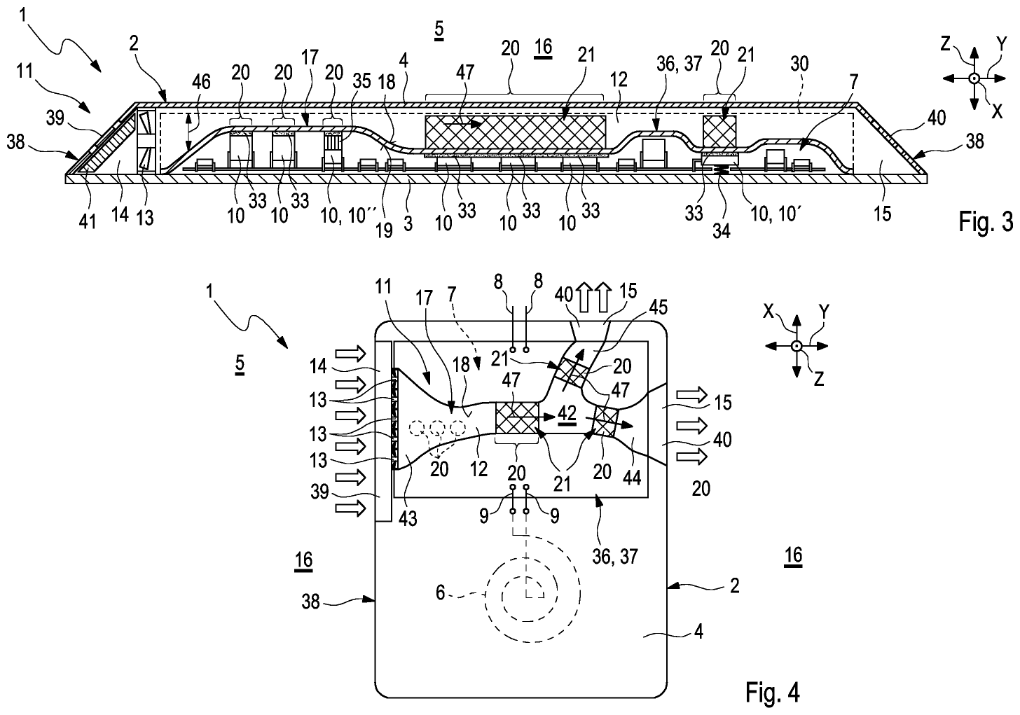

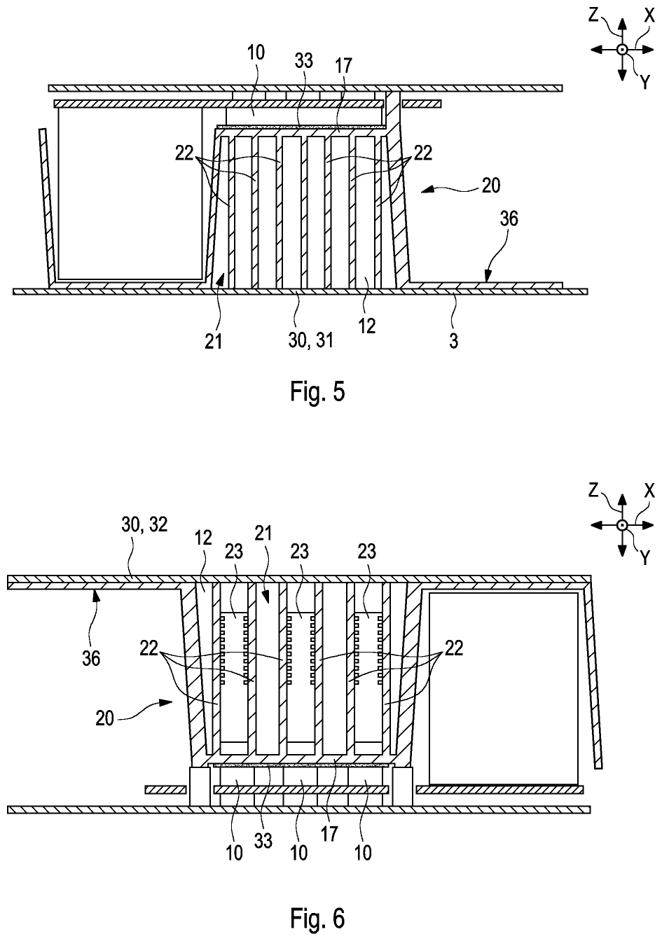

According to FIGS. 1 to 4, a stationary induction charging device 1 comprises a device housing 2, which comprises a housing base 3 and a housing cover 4, which is spaced apart from the housing base 3 in a height direction Z. In the example, the housing base 3 and the housing cover 4 are configured as flat plates that extend perpendicular to the height direction Z and accordingly extend parallel to a longitudinal direction X of the induction charging device 1 and parallel to a transverse direction Y of the induction charging device 1. The transverse direction Y extends perpendicular to the longitudinal direction X. The height direction Z extends perpendicular to the longitudinal direction X and perpendicular to the transverse direction Y. The directions are indicated by arrows in the figures. The views of FIGS. 1 and 3 run perpendicular to the longitudinal direction X. The views of FIGS. 2 and 4 run perpendicular to the height direction Z. The views of FIGS. 5 and 6 run perpendicular to the transverse direction Y as an example.

The stationary induction charging device 1 forms a component of an inductive vehicle charging system 5, which is used to charge a battery of a battery-electric vehicle. This vehicle charging system 5 also comprises a mobile induction charging device not shown here and mounted on the respective vehicle.

The stationary induction charging device 1 comprises at least one coil 6 arranged in the device housing 2 and shown in FIGS. 2 and 4 in a significantly simplified manner for generating an electromagnetic alternating field. The induction charging device 1 further comprises a power electronics 7 arranged in the device housing 2, which are concealed in FIGS. 2 and 4. The power electronics 7 serve to supply energy to the coil 6 and to control the coil 6. According to FIG. 2, the power electronics 7 can be connected to a power network via external connections 8. The power electronics 7 is electrically connected to the coil 6 via internal connections 9. The power electronics 7 comprise a plurality of components 10. Some of these components 10 generate heat during operation of the power electronics 7, which must be dissipated.

The induction charging device 1 is also equipped with an air cooling device 11 for cooling components 10 of the power electronics 7. For this purpose, the air cooling device 11 comprises at least one air shaft 12 for guiding air, which extends or is arranged in the device housing 2. The air cooling device 11 also comprises at least one blower 13 arranged in the device housing 2 for driving the air in the air shaft 12, at least one air inlet 14 and at least one air outlet 15. The air inlet 14 is fluidically connected to the surroundings 16 of the induction charging device 1. The air outlet 15 is likewise fluidically connected to its surroundings 16. During operation of the air cooling device 11, the respective blower 13 generates an air flow, which is indicated by arrows in FIGS. 2, 4 and 5. Air is drawn in from the surroundings 16, so that it enters the air shaft 12 through the air inlet 14. In the air shaft 12, the air is guided to the air outlet 15, from where it exits into the surroundings 16.

The air shaft 12 now comprises a shaft wall 17 made of metal. This shaft wall 17 has an interior wall 18 exposed to air and an exterior wall 19 facing away from the interior wall 18. At least one heat transmitter region 20 is formed in the air shaft 12. In the examples of FIGS. 1 to 4, several heat exchanger regions 20 are provided, some of which are indicated in brackets in FIGS. 1 to 4. The respective heat transmitter region 20 can expediently extend over the entire width of the air shaft 12. The heat transmitter region 20 further extends only over a longitudinal portion of the air shaft 12. The length and width of the air shaft 12 relate to the main flow direction of the air in the air shaft 12. Accordingly, the shaft length extends in the flow direction, while the shaft width extends transversely to the flow direction. In the example of FIG. 2, the air shaft 12 extends substantially parallel to the transverse direction Y of the induction charging device 1, so that in this case the shaft length extends in the transverse direction Y, while the shaft width extends in the longitudinal direction X. The shaft height runs parallel to the height direction Z.

In the examples of FIGS. 1 to 4, a plurality of such heat transfer areas 20 are formed in the air shaft 12, which are indicated in FIGS. 2 and 4 in part with a dotted line.

In these heat transfer areas 20, the shaft wall 17 is coupled on its exterior wall 19 with at least one component 10 of the power electronics 7. In this way, heat generated by the respective component 10 during operation of the power electronics 7 can be introduced into the shaft wall 17 via the exterior wall 19, as a result of which the heat is distributed over a large area within the shaft wall 17. The air flow can absorb and dissipate the heat on the inside of the wall 18.

In at least one such heat transmitter region 20, a heat transmitter structure 21 can be arranged in the air shaft 12 and on the inside of the wall 18. The respective heat transfer structure 21 can be flown through by the air and is also coupled in a heat transmitting manner to the interior of the wall 18. Therefore, heat can be transferred from the shaft wall 17 on the inside of the wall 18 to the heat transfer structure 21, which can release the heat to the air during its flow.

According to FIGS. 5 and 6, such a heat transfer structure 21 can comprise a plurality of ribs 22, which are connected to the shaft wall 17 in a heat transfer manner and can be circulated by the air. The ribs 22 expediently extend parallel to one another and in the longitudinal direction of the air shaft 12. In the example of FIG. 5, the air shaft 12 runs below the respective component 10 to be cooled. In the example of FIG. 6, the air shaft 12 runs above the respective component 10 to be cooled.

According to the embodiment shown in FIG. 6, at least one such heat transfer structure 21 can be equipped with at least one heat pipe 23. The respective heat pipe 23 can be configured as a heat pipe or as a two-phase thermosiphon. In the example of FIG. 6, the aforementioned ribs 22 are also provided. The respective heat pipe 23 is now heat-transmitting both with the shaft wall 17 and with at least one of these ribs 22, so that it can transfer heat from the shaft wall 17 to the respective rib 22. The heat is then released into the air through the ribs 22.

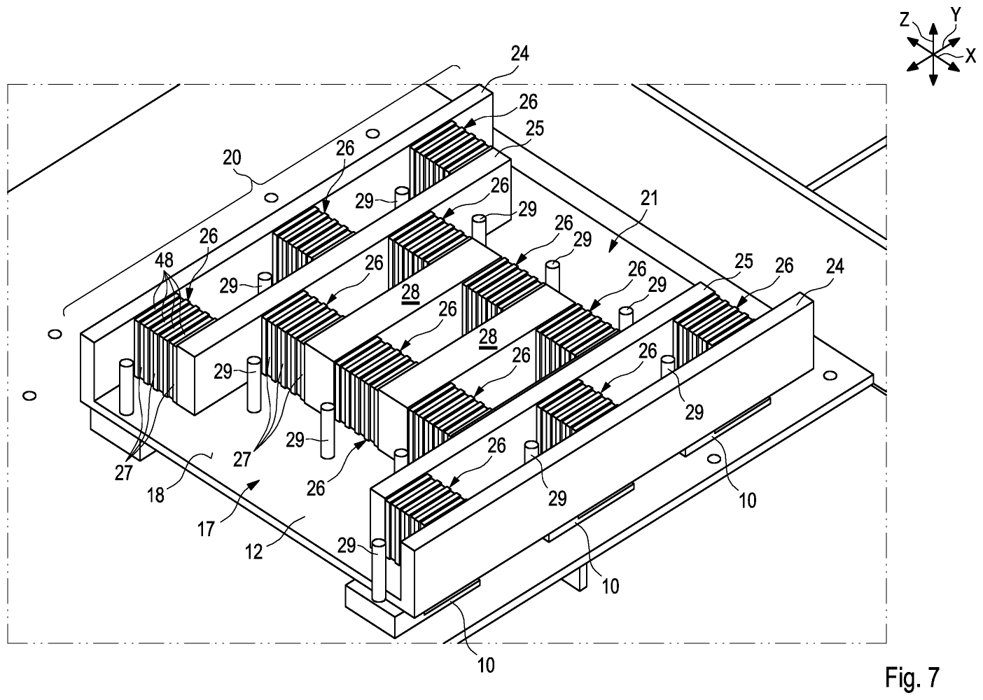

In the example of FIG. 7, the air shaft 12 is only reproduced in such a heat transfer region 20 in which a different heat transfer structure 21 is located. In this heat exchanger region 20, the air shaft 12 comprises two side walls 24 running parallel to one another, which delimit the air shaft 12 laterally, i.e. in width. Furthermore, the heat transfer structure 21 shown here is equipped with at least one rib 25, which projects from the shaft wall 17 on the inside of the wall 18 and projects into the air shaft 12. The respective rib 25 extends parallel to the respective shaft side wall 24. Furthermore, the respective rib 25 is supported by at least one flat tube block 26, in particular by a plurality of flat tube blocks 26, on the respective adjacent shaft side wall 24. In the example of FIG. 7, the respective rib 25 is supported by three such flat pipe blocks 26 on the respective adjacent shaft side wall 24. It is clear that more or fewer flat tube blocks 26 can be used here. The flat tube blocks 26 are arranged one behind the other and spaced apart from one another between the respective rib 25 and the adjacent shaft side wall 24 in the flow direction of the air.

The respective flat tube block 26 comprises a plurality of flat pipes 27 that the air can flow through, which are arranged adjacent to one another transversely to the direction of flow of the air and are connected to one another in a heat-transferring manner. In the example of FIG. 7, the respective flat tube block 26 has three such flat tubes 27. The respective flat tube block 26 comprises an outer flat tube 27 facing the respective shaft side wall 24, which is coupled in a heat transmitting manner to the respective shaft side wall 24. Furthermore, the respective flat tube block 26 comprises an inner flat tube 27 facing away from the respective side wall 24, which is coupled to the rib 25 adjacent to the respective end wall 24 in a heat-transmitting manner. The third flat pipe 27, on the other hand, forms a central flat pipe 27, which is coupled to the two other flat pipes, i.e. to the inner and the outer flat pipe 27 in a heat-transmitting manner. Special heat conductors 48 can be used for the heat-transmitting coupling of the flat pipes 27 to each other and to the shaft side wall 24 and to the rib 25, such as thermal conduction pads.

The two ribs 25, which are supported by the flat tube blocks 26 on the two shaft side walls 24, form outer ribs 25, between which at least one further rib 28 can be arranged, which is hereinafter referred to as inner rib 28. In the example of FIG. 7, two such inner ribs 28 are provided. The respective inner rib 28 is arranged on the inner side of the wall 18 and projects from the shaft wall 17. Furthermore, the respective inner rib 28 extends parallel to the outer ribs 25. The respective inner rib 28 is supported on the one hand by at least one flat tube block 26, preferably by a plurality of flat tube blocks 26, on one of the outer ribs 25. On the other hand, the inner ribs 28 shown here are supported against one another by at least one flat tube block 26, preferably by a plurality of flat tube blocks 26. In the example of FIG. 7, the inner ribs 28 are dimensioned shorter than the outer ribs 25 with respect to the shaft length. In another embodiment, the inner ribs 28 can be of equal length as or greater than the outer ribs 25. In the example of FIG. 7, the inner ribs 28 are larger in the shaft width than the outer ribs 25. In another embodiment, the inner ribs 28 in the shaft width can be the same size as or smaller than the outer ribs 25.

According to FIG. 7, the air shaft 12 can be equipped with a plurality of pressure supports 29 in the heat transmitter region 20 and in particular within the heat transmitter structure 21 and/or outside the heat transmitter regions 20. The pressure supports 29 can be circulated by the air and can transmit compressive forces acting in the horizontal direction Z, such that the air shaft 12 is relieved of these compressive forces. In particular, the pressure supports 29 can transmit the said pressure forces between the shaft wall 17 and a limiting wall 30 opposite the shaft wall 17, which is not shown in FIG. 7 and which is indicated by a dotted line in FIGS. 1 and 3. In FIG. 5, this limiting wall 30 is formed by a lower plate 31, which can in particular form the housing bottom 3. In FIG. 6, the limiting wall 30 is formed by an upper cover plate 32.

According to FIGS. 1, 3, 5 and 6, heat conductors 33 can be used to improve the heat-transmitting coupling with the outside of the wall 19 in at least one component 10. The respective heat conductor 33 can be a thermal conductive film, a thermally conductive paste, a thermally conductive gel or a thermally conductive pad.

In the example of FIG. 3, it is shown as an example that at least one component 10, which is referred to below as 10′, is pretensioned against the outside of the wall 19 by means of a spring device 34. This also improves the heat transfer to the outside of the wall 19. FIG. 3 further shows purely as an example how at least one further component 10, which is referred to below as 10″, is coupled in a heat transmitting manner to the interior of the wall 19 by means of a heat pipe 35. Functionally, this heat pipe 35 has the same structure as the heat pipes 23 described with reference to FIG. 6.

According to FIGS. 1 to 7, the shaft wall 17 can be formed by a section of a shielding plate 36. In the examples of FIGS. 1 to 4 and 6, the shielding plate 36 covers the power electronics 7 towards the bottom of the housing 3. In the example of FIG. 5, the shielding plate 36 covers the power electronics 7 towards the housing cover 4. Alternatively, the shaft wall 17 can also be formed by a section of a shielding housing 37, which is arranged in the device housing 2 and in which the power electronics 7 are arranged. In the example of FIGS. 1 to 4, this shield housing 37 is formed by the shielding plate 36 and the housing base 3. The respective section, which forms the shaft wall 17, is smaller than the associated shielding plate 36 or the associated shielding housing 37 transversely to the flow direction.

As can be seen in FIGS. 1 and 3, the shaft wall 17 can be designed such that it follows a topology of the power electronics 7 in the height direction Z. Subsequently, the air shaft 12 has a shaft height 46 measured in the height direction Z, which varies in the flow direction 47 of the air. The shaft height 46 is shown in FIGS. 1 and 3. The flow direction 47 is shown in FIGS. 1 to 4. According to FIGS. 1 and 3, the flow direction 47 of the air extends from left to right and the shaft height 46 varies recognizably from left to right.

As can be seen in FIGS. 2 and 4, the air shaft 12 can expediently be configured such that it has a channel width varying in the flow direction 47 of the air and/or a cross-section through which the air can flow in the flow direction 47. For example, in the embodiment shown in FIG. 2, the channel width and the cross-section through which the air inlet 14 can flow initially decrease, are then approximately constant in the area of the heat transfer structure 21 and then increase again up to the air outlet 15. It is noteworthy that the channel width and/or the cross-section of the air shaft 12 through which the air can flow forms a constriction in at least one of the heat transfer areas 20.

According to FIGS. 1 to 4, the device housing 2 can comprise a frame structure 38, which surrounds the device housing 2 laterally. The frame structure 38 extends around the height direction Z closed around the device housing 2. The frame structure 38 can now comprise at least one air-permeable inlet region 39, which is connected to the respective air inlet 14 in an air-guiding manner. For this purpose, the inlet region 39 can be perforated, i.e. comprise a plurality of inlet openings. The frame structure 38 can also comprise at least one outlet region 40, which is removed from the inlet region 39 and is designed to be permeable to air. Furthermore, the respective outlet region 40 is connected to the respective outlet 15 in an air-guiding manner. The air permeability of the outlet region 40 can be achieved through perforation or by using a plurality of outlet openings. In the example of FIG. 2, exactly one inlet region 39 and exactly one outlet region 40 are provided. In the example of FIG. 4, exactly one inlet region 39 and exactly two outlet regions 40 are provided.

According to FIGS. 1 to 4, at least one blower 13 can be arranged in the inlet region 38. According to FIGS. 2 and 4, five blowers 13 are arranged in parallel in the inlet area 39, purely as an example. According to FIGS. 1 and 2, a further blower 13 can be arranged in the outlet region 40. According to FIG. 2, three blowers 13 are arranged in parallel here. In the exemplary embodiment of FIGS. 3 and 4, on the other hand, no blower is arranged in the respective outlet region 40. For this purpose, in the example of FIGS. 3 and 4, an air filter 41 is arranged in the inlet region 39 in order to avoid contamination of the respective blower 13, the air shaft 12 and the heat transfer structure 21.

In the example of FIG. 2, the air shaft 12 is configured continuously such that it connects an air inlet 14 to an air outlet 15. In contrast, in the example of FIG. 4, the air shaft 12 is provided with a branch point 42, so that it comprises three shaft sections 43, 44, 45, which are fluidly connected to one another via the branch point 42. The first shaft section 43 leads from the air inlet 14 to the branch office 42. The second shaft section 44 leads from the branch 42 to a first air outlet 15. The third shaft section 45 leads from the branch office 42 to a second air outlet 15. In this case, the branch office 42 divides an incoming air flow to two outgoing air flows.

1. A stationary induction charging device for an inductive vehicle charging system for charging the battery for a battery-electric vehicle, comprising:
a device housing including a housing base and a housing cover spaced apart from the housing base in a height direction,
at least one coil located in the device housing for generating an electromagnetic alternating field,
a power electronics arranged in the device housing for supplying energy to the at least one coil and for controlling the at least one coil,
an air cooling device for cooling components of the power electronics
wherein the air cooling device has at least one air shaft running into the device housing for guiding air, at least one fan arranged in the device housing for driving the air in the at least one air shaft, at least one air inlet formed on the device housing and fluidically connecting the at least one air shaft to the surroundings, and at least one air outlet disposed on the device housing and fluidically connecting the at least one air shaft to the surroundings,
wherein the at least one air shaft comprises a shaft wall of metal, which is exposed to the air on an interior wall, and
wherein the at least one air shaft comprises at least one heat transfer area, in which the shaft wall is coupled to an exterior wall facing away from the interior wall with at least one component of the power electronics.

2. The induction charging device according to claim 1, wherein:
at least in the at least one heat transfer area, a heat transmitter structure is arranged in the at least one air shaft on the interior wall, which the air can flow through and is coupled in a heat transmitting manner to the shaft wall.

3. The induction charging device according to claim 2, wherein:
the heat transfer structure comprises ribs that can facilitate circulating the air.

4. The induction charging device according to claim 2, wherein:
the heat transfer structure comprises at least one heat pipe, which dissipates heat from the shaft wall.

5. The induction charging device according to claim 2, wherein:
the heat transfer structure comprises at least one rib which projects from the shaft wall on the inside of the interior wall, which extends parallel to a laterally delimiting shaft side wall of the at least one air shaft and which is supported on the shaft side wall via at least one flat tube block,
the at least one flat tube block comprises a plurality of flat pipes that the air can flow through, the plurality of flat pipes arranged adjacent to one another transversely to the direction of flow of the air and are connected to one another in a heat-transferring manner, and
the at least one flat tube block is coupled to the shaft side wall and to the at least one rib in a heat-transmitting manner.

6. The induction charging device according to claim 5, wherein:
the at least one flat tube block comprises an outer flat tube facing the shaft side wall, is the outer flat tube coupled in a heat transmitting manner to the shaft side wall, and an inner flat tube facing away from the shaft side wall, the inner flat tube coupled in a heat transmitting manner to the at least one rib.

7. The induction charging device according to claim 5, wherein:
the at least one air shaft in the at least one heat transfer area comprises two side walls extending parallel to one another,
the heat transfer structure arranged in the at least one heat transfer area comprises two ribs that form two outer ribs, wherein one outer rib is supported on the side wall of the shaft by the at least one flat tube block, and the other rib is supported on the other side wall of the shaft via the at least one flat tube block.

8. The induction charging device according to claim 7, wherein:
the heat transfer structure further comprises at least one inner rib that projects from the shaft wall on the interior wall, which extends parallel to the outer ribs and is arranged between the outer ribs, and
the inner rib is supported on the one hand by the at least one flat tube block on one of the outer ribs and on the other hand is supported by the at least one flat tube block on the other outer rib or on another inner rib.

9. The induction charging device according to claim 5, wherein:
the plurality of flat pipes of the at least one flat tube blocks are arranged one behind the other and spaced apart from one another in a flow direction of the air.

10. The induction charging device according to claim 1, further comprising:
a plurality of pressure supports that can be flowed around by the air are arranged in the at least one air shaft and/or in the heat transfer structure and transmit the pressure forces extending in the height direction between the shaft wall and a limiting wall of the at least one air shaft opposite the shaft wall.

11. The induction charging device according to claim 1, wherein:
at least one component of the power electronics is pretensioned against the outside of the exterior wall via a spring.

12. The induction charging device according to claim 1, wherein:
at least one component of the power electronics is coupled via a heat pipe to the exterior wall in a heat-transmitting manner.

13. The induction charging device according to claim 1, wherein:
at least one component of the power electronics is coupled via a heat conductor to the exterior wall in a heat-transmitting manner.

14. The induction charging device according to claim 1, wherein:
the shaft wall is formed by a section of a shielding plate, which covers the power electronics towards the bottom of the device housing or toward the housing cover, or
the shaft wall is formed by a section of a shielding housing, which is located in the device housing and in which the power electronics are located.

15. The induction charging device according to claim 1, wherein:
the shaft wall is adapted to a topology of the power electronics, in the height direction, so that the air at least one shaft has a shaft height measured in the height direction that varies in the flow direction of the air.

16. The induction charging device according to claim 1, wherein:
the at least one air shaft has a shaft width transverse to the direction of flow of the air that varies in the direction of flow of the air and/or a cross-section through which air can flow and varies in the direction of air flow,
the shaft width and/or the cross-section of the at least one air shaft through which the air shaft can flow forms a constriction in the at least one heat transfer area.

17. The induction charging device according to claim 1, wherein:
the device housing includes a frame structure which laterally surrounds the device housing ,
the frame structure comprises at least one air-permeable inlet region to which the respective air inlet is connected, and
the frame structure comprises at least one air-permeable outlet region which is removed from the at least one inlet region, to which the at least one respective air outlet is connected.

18. The induction charging device according to claim 17, wherein:
at least one blower is arranged at the at least one air inlet in the at least one inlet region, and/or
at least one blower is arranged at the at least one respective air outlet in the at least one outlet region, and/or
at least one blower is arranged in the at least one air shaft between the at least one air inlet and the at least one air outlet, and/or
an air filter is arranged in the at least one inlet region.

19. The induction charging device according to claim 1, wherein:
the at least one air shaft comprises at least three shaft sections, which are connected to one another via a branch, which divides an incoming air flow into at least two outgoing air flows or merges at least two incoming air flows into one outflow.

20. The induction charging device according to claim 19, wherein:
the at least one heat transfer area is formed in each of the at least three shaft sections.

21. An inductive vehicle charging system for charging a battery for a battery-electric vehicle, comprising:
a stationary induction charging device, the stationary induction charging device including:
a device housing including a housing base and a housing cover spaced apart from the housing base in a height direction,
at least one coil located in the device housing for generating an electromagnetic alternating field,
a power electronics arranged in the device housing for supplying energy to the at least one coil and for controlling the at least one coil,
an air cooling device for cooling components of the power electronics,
wherein the air cooling device has at least one air shaft running into the device housing for guiding air, at least one fan arranged in the device housing for driving the air in the at least one air shaft, at least one air inlet formed on the device housing and fluidically connecting the at least one air shaft to the surroundings, and at least one air outlet disposed on the device housing and fluidically connecting the at least one air shaft to the surroundings,
wherein the at least one air shaft comprises a shaft wall of metal, which is exposed to the air on an interior wall,
wherein the at least one air shaft comprises at least one heat transfer area, in which the shaft wall is coupled to an exterior wall facing away from the interior wall with at least one component of the power electronics, and
a mobile induction charging device, which is arranged in or on the vehicle.
